(19) United States
(12) Patent Application Publication
(10) Pub. No.: US 2011/0065286 A1
(43) Pub. Date: Mar. 17, 2011

(54) METHOD OF MANUFACTURING SEMICONDUCTOR DEVICE AND SUBSTRATE PROCESSING APPARATUS

(75) Inventors: Takafumi SASAKI, Toyama-shi (JP); Masanao FUKUDA, Toyama-shi (JP); Masayoshi MINAMI, Toyama-shi (JP); Yasuhiro MEGAWA, Toyama-shi (JP)

(73) Assignee: HITACHI-KOKUSAI ELECTRIC INC., Tokyo (JP)

(21) Appl. No.: 12/841,440

(22) Filed: Jul. 22, 2010

(30) Foreign Application Priority Data
Sep. 17, 2009 (JP) 2009-215750

(51) Int. Cl. H01L 21/71; B05C 11/00; B05C 21/00

(52) U.S. Cl. 438/770; 118/666; 257/E21.536

(57) ABSTRACT

At a low temperature of 500° C. to 700° C., the concentration of atomic oxygen is controlled in a wafer stacked direction, and the thickness distribution of oxide films is kept uniform in the wafer stacked direction. A semiconductor device manufacturing method includes a process of oxidizing substrates by supplying oxygen-containing gas and hydrogen-containing gas through a mixing part from an end side of a substrate arrangement region where the substrates are arranged inside the process chamber so that the gases flow toward the other end side of the substrate arrangement region, and supplying hydrogen-containing gas from mid-flow locations corresponding to the substrate arrangement region. The oxygen-containing gas and the hydrogen-containing gas reacts with each other in the mixing part to produce an oxidation species containing atomic oxygen, and the oxidation species has a maximum concentration at an ejection hole through which the oxidation species is ejected from the mixing part into the process chamber.

### CROSS-REFERENCE TO RELATED PATENT APPLICATION

This U.S. non-provisional patent application claims priority under 35 U.S.C. §119 of Japanese Patent Application No. 2009-215750, filed on Sep. 17, 2009, in the Japanese Patent Office, the entire contents of which are hereby incorporated by reference.

### BACKGROUND OF THE INVENTION

1. Field of the Invention

The present invention relates to a substrate processing apparatus and a method of manufacturing a semiconductor device which includes a process of treating a substrate by using the substrate processing apparatus, and more particularly, to an oxidation apparatus configured to oxidize a surface of a substrate and a method of manufacturing a semiconductor device such as an integrated circuit (IC) which includes a process of oxidizing a substrate using the oxidation apparatus.

2. Description of the Related Art

FIG. 1 is an overall view of an apparatus for manufacturing a semiconductor device (semiconductor manufacturing apparatus) as a conventional substrate processing apparatus. The conventional apparatus includes a cassette stocker 1′ that mounts wafer cassettes, a boat 3′, a wafer transfer unit (transfer device) 2′ that transfers wafers between the wafer cassette mounted on the cassette stocker 1′ and the boat 3′, a boat elevating unit (boat elevator) 4′ that loads the boat 3′ into a heat-treating furnace 5′ and unloads the boat 3′ from the heat-treating furnace 5′, and the heat-treating furnace 5′ provided with a heating unit (heater).

To explain the related art, the heat-treating furnace 5′ of the semiconductor manufacturing apparatus having the configuration of FIG. 2 is exemplified. The apparatus shown in FIG. 2 includes the boat 3′ that holds about 100 to 150 stacked wafers 6′, main nozzles 7′, sub-nozzles 8′ arranged in multiple stages, a heater 9′, a reaction tube 10′, and a gas exhaust outlet 11′. This apparatus forms silicon oxide films as oxide films on wafers 6′ such as silicon wafers by supplying, from the main nozzles 7′, O₂ gas at a flow rate of several thousands of sccm and H₂ gas at a flow rate lower than the flow rate of O₂ gas, for example, several hundreds of sccm, at a temperature of about 850° C. to 950° C. and under a low pressure environment of about 0.5 torr (67 Pa) and also by supplementarily supplying H₂ gas at a relatively low flow rate from the sub-nozzles 8′ at the same time so as to form the oxide films uniformly over the entire stacked wafers 6′. In the structure shown in FIG. 3, a shower plate 12′ is provided. Since a nozzle configured to supply hydrogen is disposed through the shower plate 12′ so as to supply hydrogen directly to the inside of a reaction tube 10′, the structure shown in FIG. 3 is substantially the same as the structure shown in FIG. 2 (refer to Patent Document 1).

It is known that the growth of an oxide film requires O₂, but the growth rate of the oxide film is extremely low if a source gas of single-substance O₂ is used under a low pressure environment of about 50 Pa. Hence, the growth rate of the oxide film gets faster when H₂ gas is added (for example, refer to Patent Document 2). Also, an oxide film is not formed in a single-substance H₂ only environment. That is, when seen as a whole, the growth of an oxide film depends on concentrations (flow rates or partial pressures) of both O₂ and H₂.

[Patent Document 1] Japanese Unexamined Patent Application Publication No. 2007-81147

[Patent Document 2] Pamphlet of International Publication No. WO2005/020309

The most characteristic film thickness distribution in the conventional apparatus is shown in FIG. 4. This is film thickness distribution of oxide films formed on wafers when O₂ gas of several thousands of sccm and H₂ gas of several hundreds of sccm are supplied as source gases from the main nozzles 7′ only in the above-described pressure and temperature zones. According to the graph of FIG. 4, the film thicknesses of oxide films formed on wafers become thinner from the top to the bottom. As described in the specification of Japanese Patent Application No. 2008-133772, filed by the present applicant, atomic oxygen O that is an intermediate product contributes to the growth of an oxide film. O₂ gas and H₂ gas supplied from the main nozzles 7′ temporarily reach a state close to a chemical equilibrium in the top area, and then, flow downward between the peripheries of wafers and the inner wall of the reaction tube 10′ while a mole fraction of each intermediate product is constantly maintained.

At this time, since a mixed gas of the source gases and the intermediate product receives flow resistance, the density of the mixed gas is high at the top and low at the bottom. Accordingly, the mole density of the atomic oxygen O changes from the top to the bottom. Therefore, the film thicknesses of oxide films formed on the wafers are different between the top and the bottom.

In addition, the atomic oxygen O is mainly consumed when oxide films are grown on the wafers. At each wafer, a predetermined amount of the atomic oxygen O necessary for growing an oxide film is consumed. For example, if about 100 wafers 6′ are stacked, O₂ gas and H₂ gas supplied through the main nozzles 7′ may flow downward between the peripheries of the wafers 6′ and the inner wall of the reaction tube 10′ as described above, and thus the concentration of atomic oxygen O may be gradually decreased from the top to the bottom due to the consumption at the surfaces of the wafers 6′.

As described above, due to two factors: one is the concentration difference of atomic oxygen O in the top-to-bottom direction caused by flow resistance acting on a downward flow; and the other is the direct effect on the concentration of the atomic oxygen O in the top-to-bottom direction caused by consumption of the atomic oxygen O at each wafer, a relatively large film thickness difference is generated between the top and bottom of a product region as shown in FIG. 4. This phenomenon is called a loading effect, and it equally occurs in a structure having a shower plate 12′ as shown in FIG. 3. In the conventional structure, in order to eliminate the loading effect, the sub-nozzles 8′ for supplying H₂ gas are arranged in multiple stages (in the cases of FIG. 2 and FIG. 3, four stages), and mass flow controllers configured to individually control the respective sub-nozzles 8′ are intervened, so as to maintain film thickness uniformity between the wafers 6′ by supplying appropriate amounts of H₂ gas.

As disclosed in the specification of Japanese Patent Application No. 2008-133772, filed by the present applicant, the consumption amount of atomic oxygen O depends on IC patterns formed on the surfaces of wafers. Therefore, when IC patterns are changed, it is necessary to adjust optimal flowrates in the height direction of the sub-nozzles 8′. For this, as disclosed in the specification by the applicant, there is a method of storing oxide film forming states of a reaction chamber in a database, performing a film-forming test once, and estimating optimal flowrates (supplementary flowrates) of H₂ gas at sub-nozzles 8′.

However, through studies, the inventors have found that film thicknesses can increase gradually from the top to the bottom of a product region, particularly, at a low temperature of 500° C. to 700° C., for example, about 600° C. This phenomenon is opposite to the loading effect, and thus will now be referred to as a reverse loading effect. In addition, according to the study of the inventors, in the above-described method (such as a method of supplementarily supplying H₂ gas through sub-nozzles 8′), it is difficult to control the concentration of atomic oxygen O in a stacked direction of wafers and prevent the reverse loading effect.

### SUMMARY OF THE INVENTION

An object of the present invention is to provide a method of manufacturing a semiconductor device at a low temperature of 500° C. to 700° C. while controlling the concentration of atomic oxygen O in a wafer stacked direction and keeping uniform the thickness distribution of oxide films in the wafer stacked direction, and a substrate processing apparatus configured to perform the method.

According to an aspect of the present invention, there is provided a method of manufacturing a semiconductor device, the method including: loading a plurality of substrates into a process chamber; oxidizing the substrates by supplying an oxygen-containing gas and a hydrogen-containing gas through a mixing part from an end side of a substrate arrangement region where the substrates are arranged inside the process chamber so that the gases flow toward the other end side of the substrate arrangement region, and supplying a hydrogen-containing gas from a plurality of mid-flow locations corresponding to the substrate arrangement region inside the process chamber; and unloading the plurality of processed substrates from the process chamber, wherein in the oxidizing of the substrates, inside temperatures of the mixing part and the process chamber are set in a range from 500° C. to 700° C., inside pressure of the mixing part is set to a first pressure lower than atmospheric pressure, inside pressure of the process chamber is set to a second pressure lower than the first pressure, and the oxygen-containing gas and the hydrogen-containing gas are allowed to react with each other in the mixing part to produce an oxidation species containing atomic oxygen, so that the oxidation species has a maximum concentration at an ejection hole through which the oxidation species is ejected from the mixing part into the process chamber.

According to another aspect of the present invention, there is provided a substrate processing apparatus including: a process chamber configured to process a plurality of substrates by oxidation; a holding tool configured to hold the substrates in the process chamber; a mixing part configured to mix an oxygen-containing gas and a hydrogen-containing gas and supply the mixture from an end side of a substrate arrangement region where the substrates are arranged inside the process chamber; a nozzle configured to supply a hydrogen-containing gas from a plurality of mid-flow locations corresponding to the substrate arrangement region inside the process chamber; an exhaust outlet configured to exhaust an inside of the process chamber so that the gases supplied into the process chamber flow toward the other end side of the substrate arrangement region; a temperature control unit configured to set inside temperature of the mixing part and the process chamber in a range from 500° C. to 700° C.; and a pressure control unit configured to set inside pressure of the mixing part to a first pressure lower than atmospheric pressure, and inside pressure of the process chamber to a second pressure lower than the first pressure, wherein the mixing part is configured such that: the oxygen-containing gas and the hydrogen-containing gas are allowed to react with each other in the mixing part to produce an oxidation species containing atomic oxygen, and the oxidation species has a maximum concentration at an ejection hole through which the oxidation species is ejected from the mixing part into the process chamber.

### BRIEF DESCRIPTION OF THE DRAWINGS

FIG. 1 is a perspective view showing an overall configuration of a semiconductor manufacturing apparatus.

FIG. 2 is a schematic sectional view showing an exemplary configuration of a heat-treating furnace of the semiconductor manufacturing apparatus.

FIG. 3 is a schematic sectional view showing another exemplary configuration of a heat-treating furnace of the semiconductor manufacturing apparatus.

FIG. 4 is a graph showing film a thickness distribution when a loading effect Occurs.

FIG. 5 is a graph showing a film thickness distribution when a loading effect occurs and a film thickness distribution when a reverse loading effect occurs, respectively.

FIG. 6 is a graph showing film thickness distribution when a reverse loading effect occurs.

FIG. 7 is a schematic sectional view showing an exemplary configuration of a heat-treating furnace in accordance with an embodiment of the present invention.

FIGS. 8A and 8B show computational fluid dynamics (CFD) calculation models, in which FIG. 8A shows a calculation model of a reaction chamber part, and FIG. 8B shows a calculation model of a shower head part and a reaction chamber part.

FIG. 9 shows a typical hydrogen-oxygen elementary reaction formula set used in CFD analysis.

FIG. 10 is a graph showing results of CFD analysis performed on a reaction chamber calculation model, in which the concentration distribution of atomic oxygen O is plotted.

FIG. 11 shows results of CFD analysis performed on a calculation model of a shower head part and a reaction chamber part, in which the concentration distribution of atomic oxygen O is plotted (when the pressure of the shower head part is about 10 torr).

FIG. 12 shows results of CFD analysis performed on a calculation model of a shower head part and a reaction chamber part, in which the concentration distribution of atomic oxygen O is plotted (when the pressure of the shower head part is about 13 torr).

FIG. 13A and FIG. 13B are a vertical sectional view and a horizontally sectional view showing a buffer chamber according to an embodiment of the present invention.

FIG. 14 is a cut-away view illustrating a modification example of the buffer chamber according to an embodiment of the present invention.

FIG. 15 is a graph showing results of an oxide film forming experiment performed using a heat-treating furnace according to an embodiment of the present invention.

FIG. 16A is a vertical sectional view showing an exemplary gate structure of a flash memory, and FIG. 16B is a vertical sectional view showing an exemplary gate structure having an oxide film formed on a sidewall.

FIG. 17 is a perspective view showing an exemplary 3D structure of a flash memory.

FIG. 18 are transmission electron microscopy (TEM) images, in which section (a) shows a TEM image of a passivation oxide film formed by conventional dry oxidation, and section (b) shows a TEM image of a passivation oxide film formed by surface oxidation of atomic oxygen O at a low temperature.

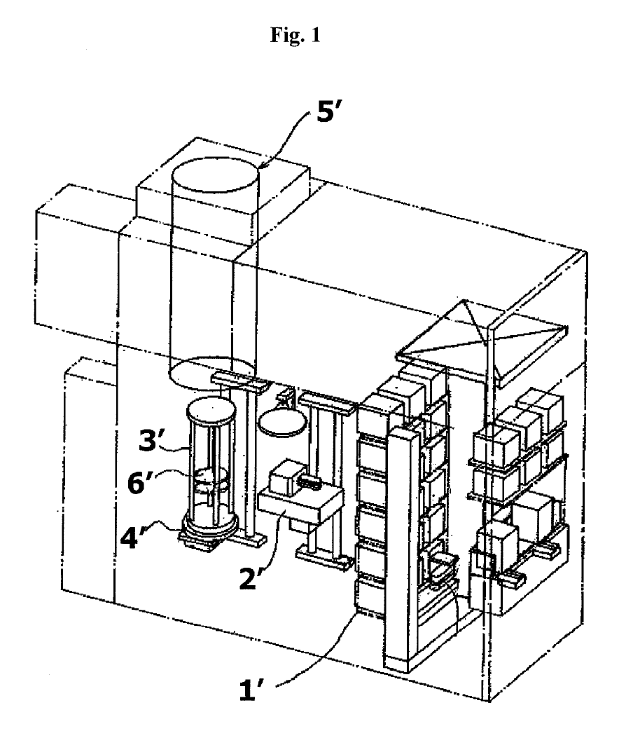

### DETAILED DESCRIPTION OF THE PREFERRED EMBODIMENTS

### Knowledge of Inventors

Hereinafter, before describing embodiments of the present invention, knowledge of the inventors will be first explained.

(Decrease of Oxide Film Forming Temperature)

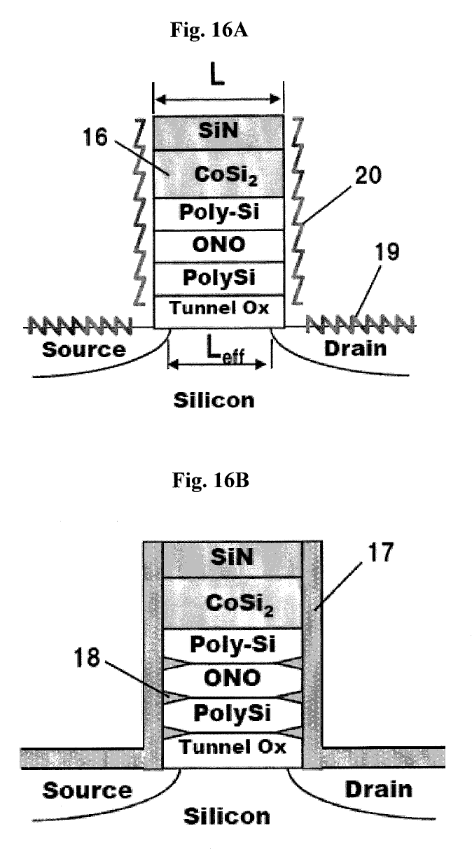

As the sizes of semiconductor devices are reduced, it is increasingly required to reduce oxide film forming temperatures. FIG. 16A and FIG. 16B show typical gate structures of flash memories. With the recent miniaturation of semiconductor devices, channel width L_{eff} is narrowed. As shown in FIG. 16A, after a gate structure is formed, if an annealing treatment is performed at 900° C. or higher or an oxide film forming process is performed, impurity ions of a source part and a drain part are diffused to a substrate made of a silicon by thermal diffusion, and thus the source part and the drain part may be connected to form a short circuit. In the case of an annealing treatment, thermal diffusion of impurity ions can be suppressed by performing a high-temperature, short-time annealing treatment (spark annealing). However, in the case of an oxide film forming process, a high-temperature, short-time process limits the growth rate of a film. Therefore, in order to suppress diffusion of impurity ions even when a process is performed for a long time, it is required to reduce the film-forming temperature.

In addition, if channel width L_{eff} is narrowed, electric resistance increases due to narrow lines. This causes line delays or increases heat generation at lines. As a method of reducing electric resistance, a metal silicide can be used as an electrode material of a control gate part. Examples of such metal silicides include MoSi₂, WSi₂, TiSi₂, CoSi₂, and NiSi, and by using them, the film-forming temperature can be reduced to, for example, 1000° C., 950° C., 750° C., and 550° C., respectively.

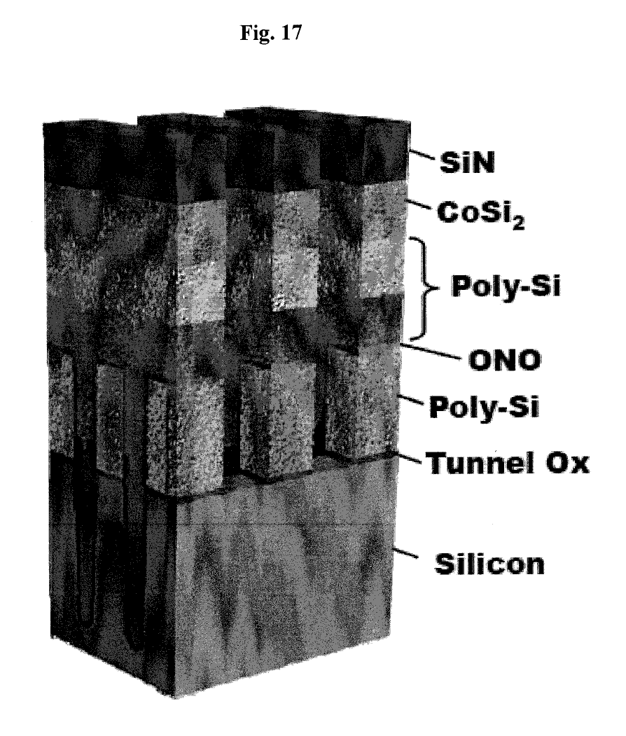

In addition, as shown in FIG. 16B, after forming a gate structure, it is necessary to form a passivation oxide film 17 as a passivation film on the sidewall of the gate structure. It is required that the passivation oxide film 17 be formed at a temperature at least lower than temperatures at which parts such as a silicide (CoSi₂) electrode 16 are formed, so as to protect parts such as the silicide electrode 16 from thermal loads. As shown in FIG. 16A, due to an etching process performed after the gate structure is formed, the source part or the drain part may receive damage 19, or the sidewall may receive damage 20. The passivation oxide film 17 may be formed to compensate for the damage 19 or the sidewall damage 20. In this case, it is required to perform a process in a manner such that existing parts such as the silicide electrode 16 may not receive thermal loads. Furthermore, as shown in FIG. 17, even when a gate Ox film (oxide film) is formed at another place in the same tip after a 3D gate structure is formed, it is necessary to perform an oxidation process at a low temperature so as to protect a silicide (CoSi₂) electrode from thermal loads.

In addition, so as to suppress transversal oxygen diffusion, it is also required to form the passivation oxide film 17 at a low temperature. In the case where the passivation oxide film 17 is formed on the sidewall of the gate structure by a conventional dry/wet oxidation method, transversal oxygen diffusion may occur at positions 18 (refer to FIG. 16B) among a tunnel Ox film, a poly-Si film, an ONO film, and a poly-Si film, and thus an oxide film called a bird's beak may be formed.

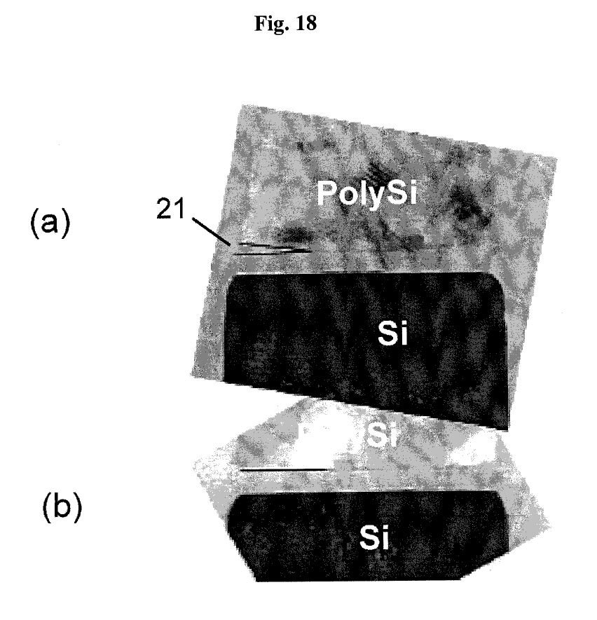

Section (a) of FIG. 18 shows a transmission electron microscopy (TEM) image of a passivation oxide film formed by conventional dry oxidation, and section (b) of FIG. 18 shows a TEM image of a passivation oxide film formed by surface oxidation of atomic oxygen O at a low temperature. As shown in section (a) of FIG. 18, at the passivation oxide film formed by conventional dry oxidation, an abnormally oxidized portion 21 having a bird's beak shape is observed. However, as shown in section (a) of FIG. 18, if strong surface oxidizing power of atomic oxygen O at a low temperature is used, since an oxide film can be formed on the surface of a sidewall before transversal diffusion proceeds, generation of an abnormal oxidized portion 21 having a bird's beak shape can be suppressed. A method of forming an oxide film using strong oxidation power of atomic oxygen O at a low temperature will be described later.

(Problems of Related Art)

As described above, it is increasingly required to reduce oxide film forming temperature. However, in the related art, if the oxide film forming temperature is kept at a low level in the range from 500° C. to 700° C., it may be difficult to improve film thickness uniformity although H₂ gas is supplied through sub-nozzles.

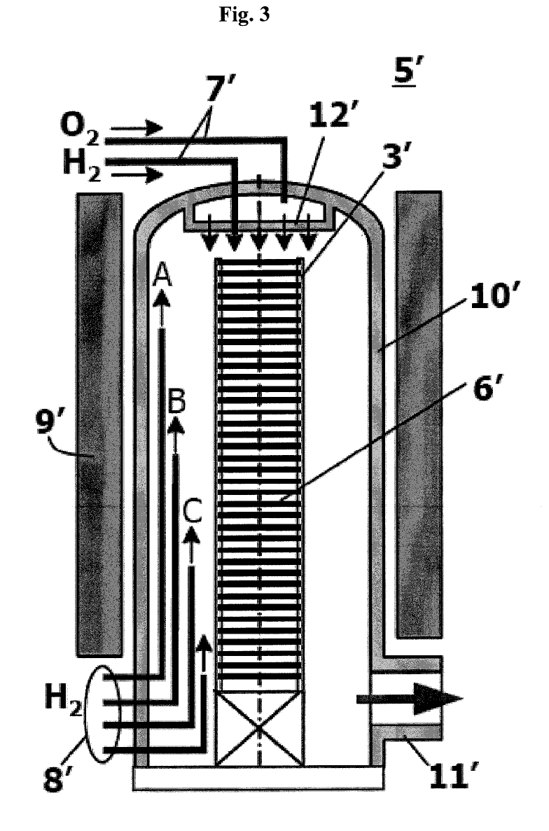

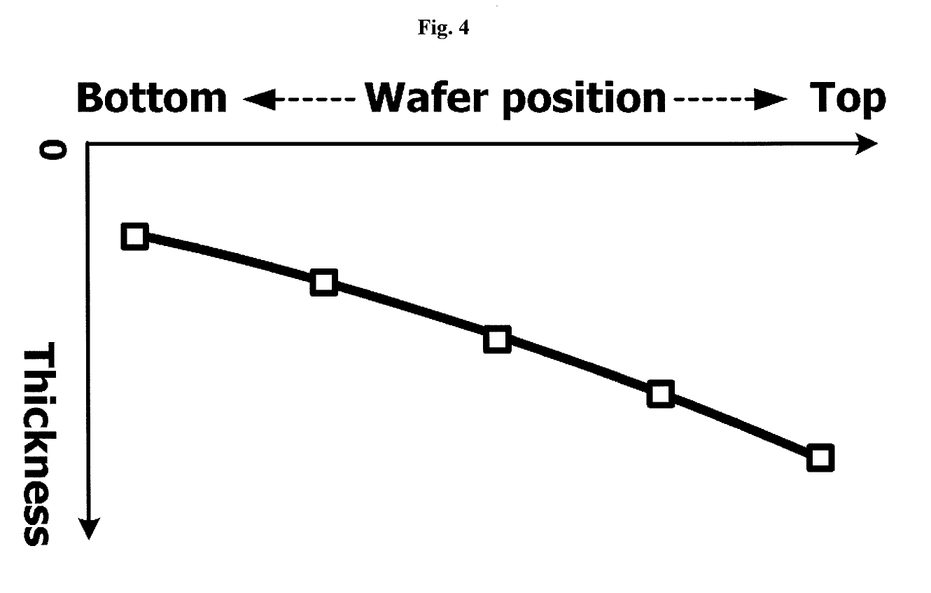

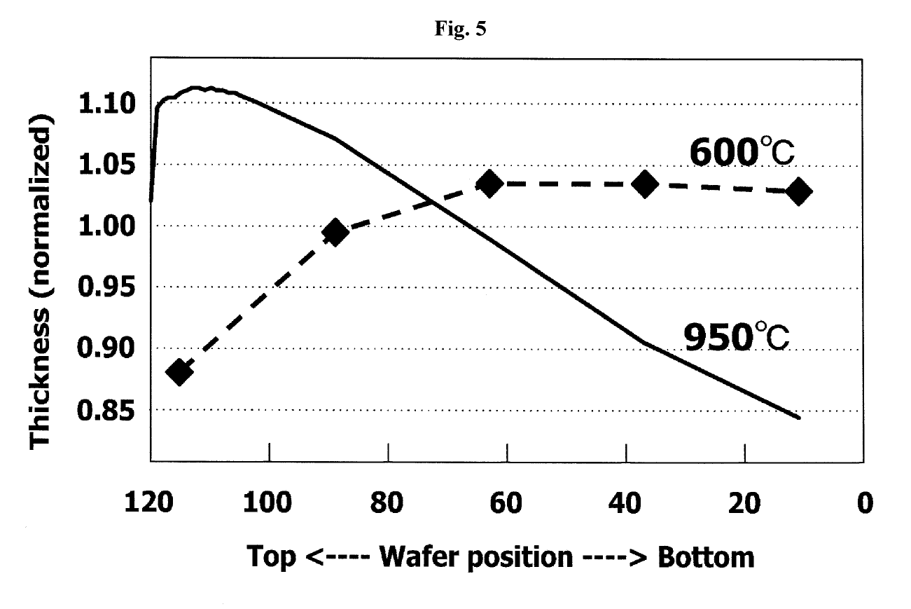

FIG. 5 shows film thickness distributions when oxide films are formed in the heat-treating furnace 5′ of FIG. 3 by supplying O₂ gas and H₂ gas through main nozzles 7′ at 950° C. and 600° C. In FIG. 5, the horizontal axis denotes the position of wafers 6′, and the vertical axis denotes the thickness of oxide films formed on the wafers 6′. In the vertical axis of FIG. 5, thicknesses normalized by the average of all film thicknesses are shown. Furthermore, in the following description, the uppermost wafer support position of the boat 3′ is denoted by #120, and the lowermost wafer support position of the boat 3′ is denoted by #1. In addition, a wafer 6′ held at an nth support position of the boat 3′ is denoted by a wafer #n.

As shown by a solid curve in FIG. 5, if oxide films are formed at a high temperature (950° C.), the thickness of the oxide films has a peak at a wafer #110 and is then decreases as it goes to a lower position. In a high-temperature reaction system of hydrogen and oxygen, reaction occurs from the moment when O₂ and H₂ are mixed with each other, and after a certain time, intermediate products become abundant. Thereafter, the intermediate products are reduced due to recombination. Reaction between hydrogen and oxygen at a low pressure (described later), for example, recombination reaction between hydrogen and oxygen at a low pressure of about 0.5 torr is relatively slow, and thus a state where intermediate products such as atomic oxygen O are abundant may continue for a relatively long time. In the thickness distribution of films formed at a high-temperature environment, the thickness is increased from the wafer #120 to the wafer #110 due to the following reason: hydrogen and oxygen are mixed with each other and start to react with each other in the reaction tube 10′ kept at a low pressure; intermediate products become abundant at a gap between peripheries of the wafers 6′ and the inner wall of the reaction tube 10′; and the concentration of atomic oxygen O is sufficiently increased at a position corresponding to the wafer #110. The thickness of the oxide films decreases gradually as it goes downward from the wafer #110 is due to the loading effect as described above.

On the other hand, as shown by a dashed curve in FIG. 5, if oxide films are formed at a low temperature (600° C.), the thickness of the oxide films increases gradually as it goes downward from the wafer #120, and a film thickness peak is observed at a wafer #60, due to the above-described reverse loading effect. According to the study of the inventors, one of factors causing the reverse loading effect is as follows: if the film-forming temperature is decreased, the reaction rate of hydrogen and oxygen is extremely lowered as compared with the decrease of the film-forming temperature, and thus it takes time until intermediate products become abundant. That is, if the film-forming temperature is decreased, decomposition reaction of hydrogen and oxygen becomes insufficient at the top position, and thus atomic oxygen O which largely contributes to the formation of oxide films has a low concentration. In this state, as it goes downward, decomposition reaction of hydrogen and oxygen proceeds gradually to increase the concentration of the atomic oxygen O, and thus the film thickness increases.

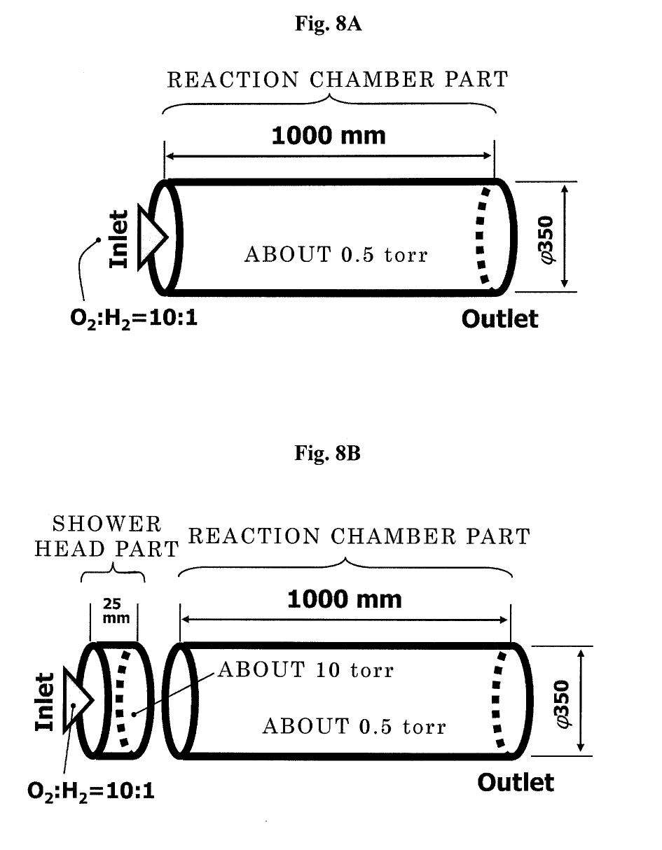

Regarding this phenomena, hydrogen and oxygen elementary reaction analysis (computational fluid dynamics (CFD) analysis) was performed, and a description thereof will now be given. FIG. 8A shows a calculation model of a reaction chamber part for CFD analysis. For example, the calculation model was used to simulate variations of gas composition with respect to the distance from an inlet, that is, with respect to gas stay time, when O₂ gas and H₂ gas are simultaneously supplied to a cylindrical gas passage (reaction chamber part) which has a distance of 1000 mm between the inlet (gas inlet) and an outlet (gas outlet) and an inner diameter of φ350 mm. In the calculation model of FIG. 8A, gas stay time during which gas travels from the inlet to the outlet is very short at about 0.136 seconds. That is, gas momentarily escapes from the calculation model.

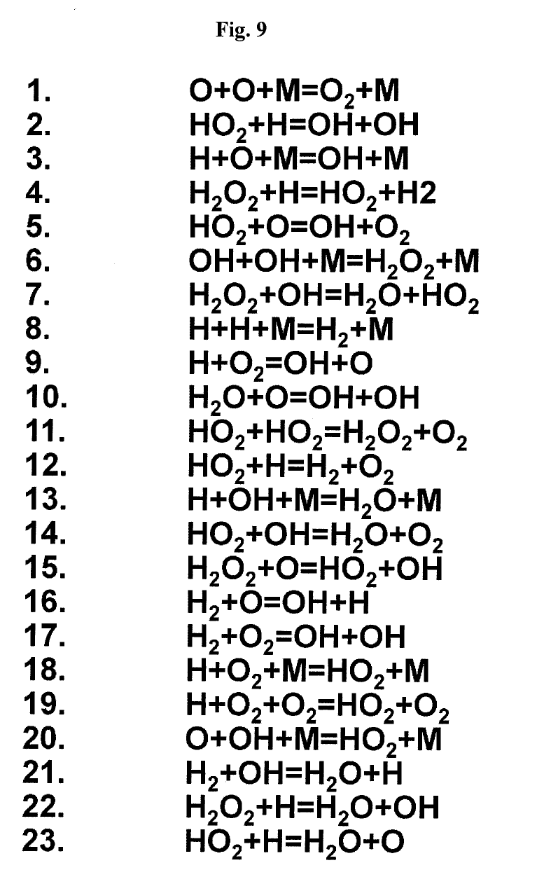

As disclosed in the specification of Japanese Patent Application No. 2008-133772, filed by the present applicant, since the concentration of atomic oxygen O is directly related with film thickness distribution, attention is paid on concentration distribution of atomic oxygen O. FIG. 9 shows a typical hydrogen-oxygen elementary reaction formula set used in the CFD analysis. The formulas are reaction formulas expressing combustion of hydrogen and oxygen, and the reaction between H₂ and O₂ by which H₂O is produced as a main product is expressed by twenty three elementary reactions. For example, at about atmospheric pressure, combustion reaction of H₂ and O₂ is completed within a short time, and finally, H₂O is generated. However, during the reaction, various intermediate product species such as O, H, OH, H₂O₂, and HO₂ are produced and react with each other.

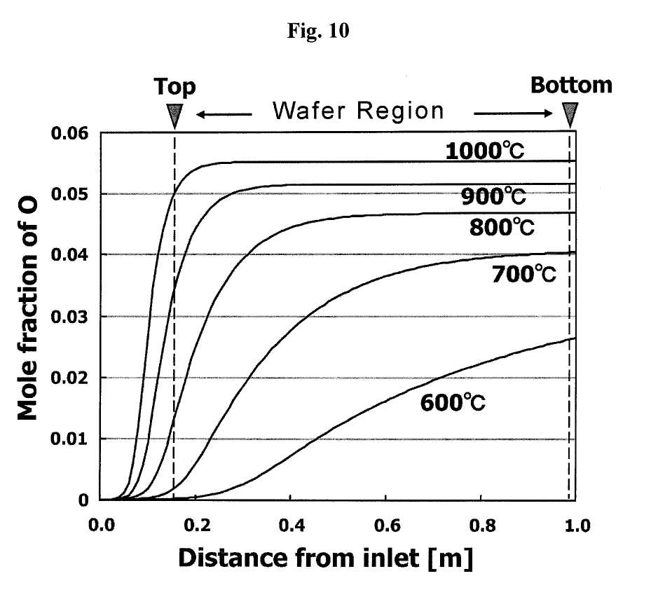

In a condition where O₂ gas and H₂ gas are supplied to the reaction chamber part of FIG. 8A at a ratio of O₂:H₂=10:1 while varying the temperature from a high temperature (1000° C.) to a low temperature (600° C.), mole fraction of atomic oxygen O calculated using the elementary reaction formula set is shown in FIG. 10. FIG. 10 shows results of CFD analysis on the calculation model of FIG. 8A, in which the concentration distribution of atomic oxygen O is plotted. In FIG. 10, the horizontal axis denotes the distance from the inlet (stay time), and the vertical axis denotes mole faction of atomic oxygen O.

Referring to FIG. 10, in the case where the temperature is high (for example, refer to 1000° C. curve), the mole fraction of atomic oxygen O is immediately increases to about 5.5% at a position close to the inlet. Thereafter, the mole fraction of the atomic oxygen O is almost constant until the outlet. In general, a relatively high concentration of atomic oxygen O is decreased close to zero due to recombination; however, since the distance to the outlet is short, the concentration of the atomic oxygen O is almost constant. That is, before the concentration of the atomic oxygen O decreases, the atomic oxygen O is exhausted through the outlet. In FIG. 10, a region corresponding to a wafer stacked region is indicated. That is, in FIG. 10, “Wafer Region” is corresponding to the wafer stacked region, a position indicated by “Top” is corresponding to the uppermost wafer, and a position indicated by “Bottom” is corresponding to the lowermost wafer. In the concentration distribution of atomic oxygen O at a high temperature, the concentration at a position slightly lower than a position corresponding to the uppermost wafer is higher than the concentration at the position corresponding to the uppermost wafer. This is similar to the film thickness distribution of the 950° C. curve of FIG. 5 in a region from about the wafer #120 to the wafer #110. Since atomic oxygen O is consumed at the surfaces of wafers when oxide films are actually formed, the calculated concentration of atomic oxygen O shown in FIG. 10 is also reduced as it goes from the inlet to the outlet. When this is considered, it could be understood that the concentration distribution of the atomic oxygen O in the “Wafer Region” of FIG. 10 is well corresponding to the film thickness distribution (the film thickness distribution of the 950° C. curve) of FIG. 5 indicated by a solid curve.

On the other hand, in the case where the temperature is low (for example, refer to 650° C. curve), the mole fraction of atomic oxygen O is low at a position close to the inlet and gradually increases as it goes from the inlet to the outlet. This distribution is well corresponding to the film thickness distribution (the film thickness distribution of the 650° C. curve) of FIG. 5 indicated by a broken curve.

That is, if the inside temperature of the reaction chamber part is high, gas-phase reaction between hydrogen and oxygen proceeds rapidly, and atomic oxygen O is abundantly generated at the top side of stacked wafers and temporarily kept in equilibrium state. Then, as it goes to the bottom side, the film thickness gradually decreases due to consumption of the atomic oxygen O at the surfaces of the wafers and pressure loss. On the other hand, if the inside temperature of the reaction chamber part is low, the gas-phase reaction between hydrogen and oxygen proceeds slowly, and thus, atomic oxygen O is insufficient at the top side of the stacked wafers to make small the film thickness. Then, as it goes to the bottom side, the reaction between hydrogen and oxygen proceeds gradually to produce atomic oxygen abundantly, and thus the film thickness increases gradually. That is, since the concentration of atomic oxygen O increases gradually in the reaction chamber part, the thickness of oxide films is also gradually increased from the top side to the bottom side according to the concentration of the atomic oxygen O; i.e., reverse loading effect occurs. Although atomic oxygen O is also consumed at the surfaces of the wafers in a low-temperature condition, as it goes to the bottom side, the concentration of the atomic oxygen O increases since gas-phase reaction increases furthermore.

According to the study of the inventors, in the case of the above-described low-temperature reaction behavior, film thickness distribution may not be corrected although hydrogen is supplementarily supplied through sub-nozzles. This is described below.

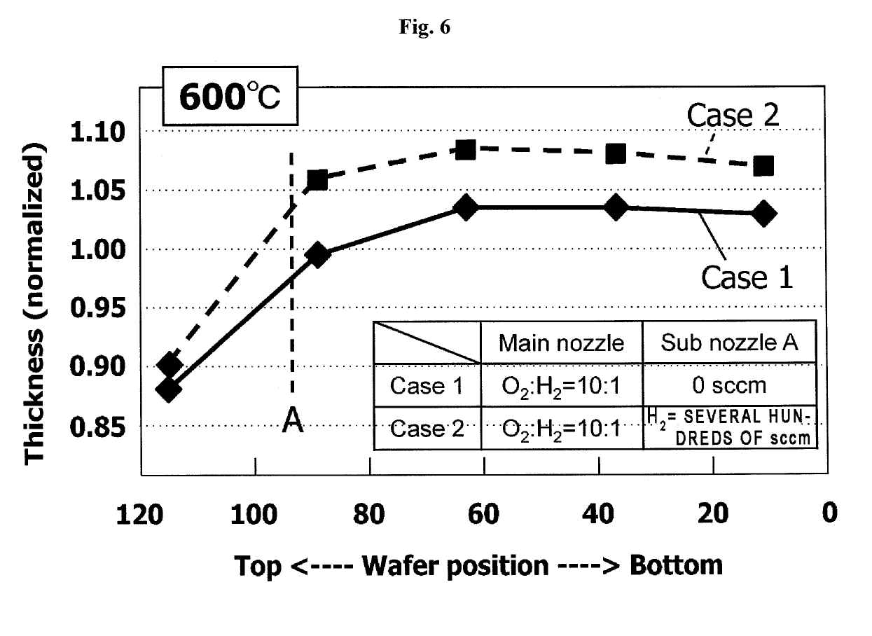

FIG. 6 is a graph for showing an exemplary attempt to make uniform the film thickness distributions obtained by using the heat-treating furnace 5′ of FIG. 3 and supplying hydrogen through the sub-nozzles 8′ and a gas through main nozzles 7′. In FIG. 6, the horizontal axis denotes the position of wafers 6′, and the vertical axis denotes the thickness of oxide films formed on the wafers 6′. In the vertical axis of FIG. 6, thicknesses normalized by the average of all film thicknesses are shown.

In the case 1 of FIG. 6 (indicated by a solid curve), the inside temperature of the reaction tube 10′ is kept at 600° C.; O₂ gas and H₂ gas are supplied through the main nozzles 7′ at a ratio of O₂:H₂=10:1 but H₂ gas is not supplementarily supplied through the sub-nozzles 8′. In the case 2 of FIG. 6 (indicated by a broken curve), the inside temperature of the reaction tube 10′ is kept at 600° C.; O₂ gas and H₂ gas are supplied through the main nozzles 7′ at a ratio of O₂:H₂=10:1; and along with this, H₂ gas is supplementarily supplied through one of the sub-nozzles 8′ which is indicated by A in FIG. 3 (corresponding to a broken line A in FIG. 6) at a flowrate of several hundreds of sccm, so as to correct the film thickness of a wafer #90 to a level similar to the film thickness of wafers disposed lower than the wafer #60.

In the case 2 of FIG. 6, (indicated by the broken curve), the film thickness is increased at about the wafer #90; however, at the same time, the film thickness is also increased at the lower wafers such that the film thickness of the wafer #90 cannot be made similar to the film thickness of the lower wafers. That is, in the case 1 where O₂ gas and H₂ gas are supplied only through the main nozzles 7′ and the film thickness increases from the top side to the bottom side by the reverse loading effect, the film thickness distribution cannot be corrected although H₂ gas is supplementarily supplied through the sub-nozzles 8′. Furthermore, in the case 2 of FIG. 6 (indicated by a broken curve), although the film thickness of the wafer #90 is increased, the film thickness of a wafer #115 or neighboring wafers is little increased: that is, reversely, the film thickness distribution along the stacked direction of the wafers is worsened. One of reasons for this is considered as follows. As disclosed in the specification of Japanese Patent Application No. 2008-133772, filed by the present applicant, if H₂ gas is supplied to an upstream side, although the thicknesses of downstream-side wafers are increased, the thickness of an upstream-side wafer is not largely increased. In addition, this effect occurs independent of the position of the sub-nozzle 8′ through which hydrogen is supplementarily supplied.

(Knowledge of Inventors)

The inventors have studied to solve the above-described problems. As a result, the inventors have obtained the following knowledge. For example, in the case where O₂ gas and H₂ gas are supplied only through the main nozzles 7′ at a low temperature range from 500° C. to 700° C., the above-described problems can be solved by making a trend (similar to the case of a loading effect) in which the film thickness is gradually decreased from the top side to the bottom side, for example, like the film formation result shown by a solid curve (950° C.) in FIG. 5. That is, the inventors have found that if such a trend is made, film thickness distribution can be effectively corrected by supplementarily supplying H₂ gas through the sub-nozzle 8′. In addition, the inventors have found that it is necessary to facilitate decomposition of gas at the upstream side of a gas flow, that is, at a position close to the main nozzles 7′ so as to realize such a trend. The present invention is proposed based on the knowledge of the inventors.

### Embodiment of Invention

Hereinafter, an explanation will be given on an embodiment of the present invention based on the above-described knowledge of the inventors with reference to the attached drawings.

(1) Structure of Substrate Processing Apparatus

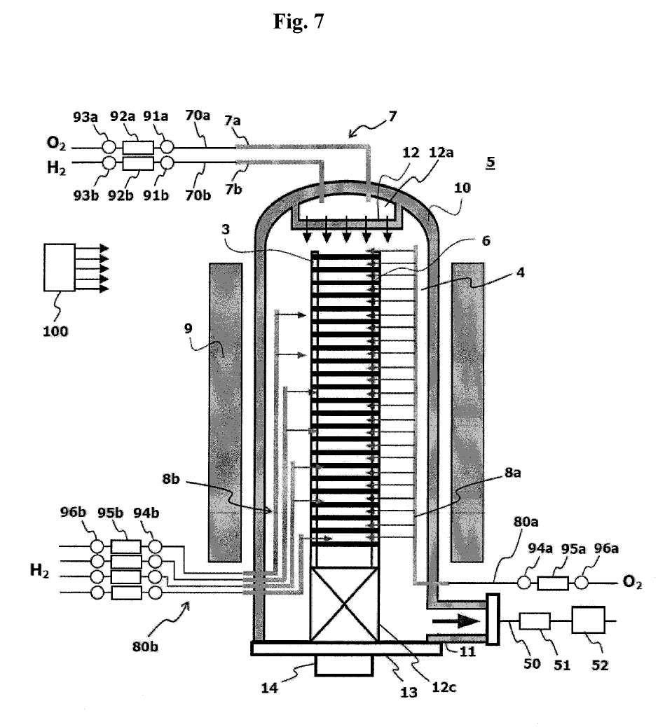

First, as a substrate processing apparatus in accordance with an embodiment of the present invention, a batch-type vertical semiconductor manufacturing apparatus (oxidation apparatus) will be described with reference to FIG. 7. FIG. 7 is a schematic sectional view showing a configuration example of a heat-treating furnace (oxidation furnace) relevant to the current embodiment of the present invention. FIG. 7 illustrates an exemplary structure of a heat-treating furnace 5 of a substrate processing apparatus whose maximum loading capacity is for example 120 wafers.

As shown in FIG. 7, the heat-treating furnace 5 of the substrate processing apparatus relevant to the current embodiment includes a heater 9 as a heat source. The heater 9 is cylindrically-shaped and is supported on a heater base (not shown) used as a holding plate so that the heater 9 is vertically installed. At the inside of the heater 9, a reaction tube 10 is installed concentrically with the heater 9. A process chamber (reaction chamber) 4 configured to process a plurality of substrates by oxidation is formed inside the reaction tube 10. The process chamber 4 is configured such that a boat 3 used as a substrate holding tool can be loaded into the process chamber 4. The boat 3 is configured to hold a plurality of wafers 6 such as silicon wafers as substrates in a state where the wafers 6 are horizontally positioned and arranged in multiple stages with gaps (substrate pitch distances). In the following description, a wafer support position of an uppermost stage inside the boat 3 is represented by #120, and a wafer support position of a lowermost stage is represented by #1. In addition, a wafer 6 held at a support position of an nth stage from the lowermost stage inside the boat 3 is represented by a wafer #n.

A lower portion of the reaction tube 10 is opened so that the boat 3 can be inserted therethrough. The opening of the reaction tube 10 is tightly closed with a seal cap 13. On the seal cap 13, a heat insulation cap 12c that supports the boat 3 from the lower side is installed. The heat insulation cap 12c is mounted on a rotation mechanism 14 through a rotation shaft (not shown) which is installed through the seal cap 13. The rotation mechanism 14 is configured to rotate the heat insulation cap 12c and the boat 3 through the rotation shaft so that the wafers 6 supported on the boat 3 can be rotated.

A shower plate 12 is installed on a ceiling wall of the reaction tube 10, and a buffer chamber 12a as a mixing space is formed by the ceiling wall of the reaction tube 10 and the shower plate 12. Above the reaction tube 10, an oxygen supply nozzle 7a that supplies oxygen (O₂) gas as oxygen-containing gas from the upper side of the process chamber 4 to wafers 6, and a hydrogen supply nozzle 7b that supplies hydrogen (H₂) gas as hydrogen-containing gas from the upper side of the process chamber 4 to wafers 6 are connected to communicate with the inside of the buffer chamber 12a. A gas injection hole of the oxygen supply nozzle 7a is directed downward and configured to inject oxygen gas downward from the upper side of the process chamber 4 (along a wafer stack direction). A gas injection hole of the hydrogen supply nozzle 7b is directed downward and configured to inject hydrogen gas downward from the upper side of the process chamber 4 (along a wafer stack direction). O₂ gas supplied through the oxygen supply nozzle 7a and H₂ gas supplied through the hydrogen supply nozzle 7b are mixed at the inside of the buffer chamber 12a and then supplied into the process chamber 4 through the shower plate 12. That is, the buffer chamber 12a is configured as a mixing part that mixes O₂ gas which is an oxygen-containing gas with H₂ gas which is a hydrogen-containing gas and supplies the mixture through an end of a wafer arrangement region of the inside of the process chamber 4 where a plurality of wafers 6 are arranged. A main nozzle 7 is configured by the oxygen supply nozzle 7a and the hydrogen supply nozzle 7b. In addition, the shower plate 12 is provided with gas ejection holes that supply O₂ gas and H₂ gas in a shower manner from one end toward the other end of the wafer arrangement region where a plurality wafers 6 are arranged.

An oxygen supply pipe 70a as an oxygen gas supply line is connected to the oxygen supply nozzle 7a. At the oxygen supply pipe 70a, an oxygen gas supply source (not shown), an on-off valve 93a, a mass flow controller (MFC) 92a as a flow rate control unit (flow rate controller), and an on-off valve 91a are installed sequentially from the upstream side of the oxygen supply pipe 70a. In addition, a hydrogen supply pipe 70b as a hydrogen gas supply line is connected to the hydrogen supply nozzle 7b. At the hydrogen supply pipe 70b, a hydrogen gas supply source (not shown), an on-off valve 93b, a mass flow controller (MFC) 92b as a flow rate control unit (flow rate controller), and an on-off valve 91b are installed sequentially from the upstream side of the hydrogen supply pipe 70b.

A hydrogen supply nozzle 8b, through which H₂ gas as hydrogen-containing gas is supplied from the lateral side of the inside of the process chamber 4 to the wafers 6, is connected to the side lower part of the reaction tube 10 in a manner such that the hydrogen supply nozzle 8b penetrates the sidewall of the reaction tube 10. The hydrogen supply nozzle 8b is disposed in a region corresponding to the wafer arrangement region, that is, a cylindrical region surrounding the wafer arrangement region to face the wafer arrangement region at the inside of the reaction tube 10. The hydrogen supply nozzle 8b is configured by a plurality of (in this embodiment, four) L-shaped nozzles each having a different length. Each of the plurality of nozzles of the hydrogen supply nozzle 8b extends upward along the inner wall of the sidewall of the reaction tube 10. The plurality of nozzles constituting the hydrogen supply nozzle 8b have different lengths in the wafer arrangement direction. H₂ gas is supplied into the reaction tube 10 from a plurality of (in this embodiment, seven) locations of the region corresponding to the wafer arrangement region. Thus, a hydrogen concentration inside the reaction chamber 4 in the wafer arrangement direction (vertical direction) can be adjusted. The hydrogen supply nozzle 8b is installed along the inner wall at a position nearer the inner wall of the sidewall of the reaction tube 10 than the wafers 6. A hydrogen sub-nozzle is configured by the hydrogen supply nozzle 8b. In addition, a first nozzle is configured by the hydrogen supply nozzle 8b.

Top surfaces of tips of the plurality of nozzles constituting the hydrogen supply nozzle 8b are closed. At least one gas ejection hole is formed in a side surface of the tip portion of each nozzle. In FIG. 7, arrows extending from the hydrogen supply nozzle 8b toward the wafers 6 represent H₂ gas ejection directions from the respective gas ejection holes. Root parts of the arrows represent the respective gas ejection holes. That is, the gas ejection holes are directed toward sides of the wafers 6 and are configured to eject H₂ gas in the process chamber 4 from the lateral side to the wafers 6 in horizontal directions (in directions along principal surfaces of the wafers 6). In the case of the current embodiment, each of the longest nozzle, the second longest nozzle and the third longest nozzle is provided with two gas ejection holes, and the shortest nozzle is provided with one gas ejection hole. The plurality of (in this embodiment, seven) gas ejection holes are installed at regular intervals. The lower gas ejection hole of the longest nozzle is formed at an intermediate position between the upper gas ejection hole of the longest nozzle and the upper gas ejection hole of the second longest nozzle. In addition, the lower gas ejection hole of the second longest nozzle is formed at an intermediate position between the upper gas ejection hole of the second longest nozzle and the upper gas ejection hole of the third longest nozzle. In addition, the lower gas ejection hole of the third longest nozzle is formed at an intermediate position between the upper gas ejection hole of the third longest nozzle and the gas ejection hole of the shortest nozzle. This disposition of the gas ejection holes makes it possible to supply H₂ gas that is finely adjusted in the wafer arrangement direction, and thus, the hydrogen concentration can be finely adjusted. A first gas ejection hole is configured by these gas ejection holes.

A hydrogen supply pipe 80b as a hydrogen gas supply line is connected to the hydrogen supply nozzle 8b. The hydrogen supply pipe 80b is configured by a plurality of (in this embodiment, four) pipes that are connected to the plurality of nozzles constituting the hydrogen supply nozzle 8b, respectively. At the hydrogen supply pipe 80b, a hydrogen gas supply source (not shown), an on-off valve 96b, a mass flow controller (MFC) 95b as a flow rate control unit (flow rate controller), and an on-off valve 94b are installed sequentially from a upstream side. The on-off valve 96b, the mass flow controller 95b, and the on-off valve 94b are installed in each of the pipes constituting the hydrogen supply pipe 80b and configured to independently control an H₂ gas flow rate at each of the nozzles constituting the hydrogen supply nozzle 8b.

An oxygen supply nozzle 8a, through which O₂ gas as oxygen-containing gas is supplied from the side of the inside of the process chamber 4 to the wafers 6 is connected to the side lower part of the reaction tube 10 in a manner such that the oxygen supply nozzle 8a penetrate the sidewall of the reaction tube 10. The oxygen supply nozzle 8a is disposed in a region corresponding to the wafer arrangement region, that is, a cylindrical region surrounding the wafer arrangement region to face the wafer arrangement region at the inside of the reaction tube 10. The oxygen supply nozzle 8a is configured by a single nozzle (multi-hole nozzle) having a plurality of gas injection holes, and extends upward to a wafer of the uppermost stage along the inner wall of the sidewall of the reaction tube 10. That is, the oxygen supply nozzle 8a extends along the entire wafer arrangement region. A second nozzle is configured by the oxygen supply nozzle 8a.

In FIG. 7, arrows extending from the oxygen supply nozzle 8a toward the wafers 6 represent O₂ gas ejection directions from the respective gas ejection holes, and root parts of the arrows represent the respective gas ejection holes. That is, in order to uniformly supply O₂ gas to each of the process wafers, the oxygen supply nozzle 8a is provided with as many gas ejection holes as at least the process wafers so that the gas ejection holes are in 1:1 correspondence with the plurality of process wafers. For example, when the number of the process wafers is 120 sheets, at least 120 gas ejection holes are installed so that they correspond to the respective process wafers. Moreover, for example, in the case where side dummy wafers are arranged above and under the process wafers and the numbers of upper dummy wafers, process wafers, and lower dummy wafers are 10 sheets, 100 sheets, and 10 sheets, respectively, at least 100 gas ejection holes are installed so that they correspond to at least the 100 process wafers.

In addition to the configuration in which as many gas ejection holes as the process wafers are formed so that they correspond to the respective process wafers, gas ejection holes may be also formed at locations that do not correspond to the process wafers, that is, regions other than the wafer arrangement area. For example, gas ejection holes may be formed in a region corresponding to a dummy wafer arrangement region where the above-described side dummy wafers are arranged, or a region above or under the corresponding region. When gas ejection holes are formed in the region corresponding to the dummy wafer arrangement region, it may be preferable that as many gas ejection holes as the dummy wafers be formed so that they correspond to the respective dummy wafers in the region adjacent to at least the process wafers. In this way, the flow of O₂ gas to the dummy wafers in the region adjacent to the process wafers may be made to be equal to the flow of O₂ gas to the process wafers, and may be made not to disturb the flow of gas to the process wafers disposed in the vicinity of the dummy wafers.

The gas ejection holes have relatively small hole sizes so that O₂ gas is ejected to the respective process wafers at a uniform flow rate. The oxygen supply nozzle 8a is configured by, for example, a multi-hole nozzle in which as many holes of about φ0.5-1 mm as the process wafers are installed in a pipe of about φ10-20 mm. The oxygen supply nozzle 8a may be configured to supply O₂ gas uniformly to all the process wafers, and may be configured by a plurality of nozzles each having a different length, just like the hydrogen supply nozzle 8b. A second gas ejection hole is configured by the gas ejection holes formed in the oxygen supply nozzle 8a.

In the current embodiment, the arrangement pitch of the gas ejection holes provided in the oxygen supply nozzle 8a is set to be equal to the wafer arrangement pitch. In addition, the respective distances between the respective gas ejection holes provided in the oxygen supply nozzle 8a and the respective wafers corresponding to the respective gas ejection holes in the wafer arrangement direction are set to be equal to one another. Moreover, the number of the gas ejection holes provided in the hydrogen supply nozzle 8b is set to be smaller than the number of the gas ejection holes provided in the oxygen supply nozzle 8a.

An oxygen supply pipe 80a as an oxygen gas supply line is connected to the oxygen supply nozzle 8a. At the oxygen supply pipe 80a, an oxygen gas supply source (not shown), an on-off valve 96a, a mass flow controller (MFC) 95a as a flow rate control unit (flow rate controller), and an on-off valve 94a are installed sequentially from the upstream side of the oxygen supply pipe 80a.

A main oxygen gas supply system is mainly configured by the oxygen supply nozzle 7a, the oxygen supply pipe 70a, the on-off valve 91a, the mass flow controller 92a, and the on-off valve 93a. In addition, a sub oxygen gas supply system is mainly configured by the oxygen supply nozzle 8a, the oxygen supply pipe 80a, the on-off valve 94a, the mass flow controller 95a, and the on-off valve 96a. In addition, an oxygen gas supply system is configured by the main oxygen gas supply system and the sub oxygen supply system.

A main hydrogen gas supply system is mainly configured by the hydrogen supply nozzle 7b, the hydrogen supply pipe 70b, the on-off valve 91b, the mass flow controller 92b, and the on-off valve 93b. In addition, a sub hydrogen gas supply system is mainly configured by the hydrogen supply nozzle 8b, the hydrogen supply pipe 80b, the on-off valve 94b, the mass flow controller 95b, and the on-off valve 96b. In addition, a hydrogen gas supply system is configured by the main hydrogen gas supply system and the sub hydrogen supply system.

In addition, a nitrogen gas supply system (not shown) is connected to the oxygen gas supply system and the hydrogen gas supply system. The nitrogen gas supply system is configured to supply nitrogen (N₂) gas as inert gas into the process chamber 4 through the oxygen supply pipes 70a and 80a and the hydrogen supply pipes 70b and 80b. The nitrogen gas supply system is mainly configured by a nitrogen supply pipe (not shown), an on-off valve (not shown), and a mass flow controller (not shown).

At a side lower part of the reaction tube 10, a gas exhaust outlet 11 that exhausts the inside of the process chamber is installed. A gas exhaust pipe 50 as a gas exhaust line is connected to the gas exhaust outlet 11. At the gas exhaust pipe 50, an auto pressure controller (APC) 51 as a pressure regulation unit (pressure controller), and a vacuum pump 52 as an exhaust unit (exhaust device) are installed sequentially from the upstream side of the gas exhaust pipe 50. An exhaust system is mainly configured by the gas exhaust outlet 11, the gas exhaust pipe 50, the APC 51, and the vacuum pump 52.

The respective parts of the substrate processing apparatus, such as the heater 9, the mass flow controllers 92a, 92b, 95a and 95b, the on-off valves 91a, 91b, 93a, 93b, 94a, 94b, 96a and 96b, the APC 51, the vacuum pump 52, and the rotation mechanism 14, are connected to a controller 100 as a control unit (control part), and the controller 100 is configured to control the operations of the respective parts of the substrate processing apparatus. The controller 100 is configured as a computer including a CPU, a storage device such as a memory or a hard disk drive (HDD), a display device such as a flat panel display (FPD), and an input device such as a keyboard or a mouse. In addition, the controller 100 also functions as a temperature control unit that controls the temperature of the heater 9 to keep the insides of the buffer chamber 12a and the process chamber 4 at a predetermined temperature (for example, in the range from 500° C. to 700° C.).

(2) Substrate Processing Process

Next, an explanation will be given on a method of oxidizing a wafer as a substrate, which is one of semiconductor device manufacturing processes, by using the heat-treating furnace 5 of the oxidation apparatus. In the following description, the operations of the respective parts constituting the oxidation apparatus are controlled by the controller 100.

1-batch quantity (for example 120 sheets) of wafers 6 are transferred and charged into the boat 3 by the substrate transfer device (wafer charge). Then, the boat 3 charged with the plurality of wafers 6 is loaded into the process chamber 4 of the heat-treating furnace 5 that is maintained in a heated state by the heater 9, and the inside of the reaction tube 10 is sealed by the seal cap 13. Subsequently, the inside of the reaction tube chamber 10 is vacuum-evacuated by the vacuum pump 52, and by the APC 51, the inside pressure of the buffer chamber 12a is adjusted to a first pressure lower than atmospheric pressure and the inside pressure of the reaction tube 10 (in-furnace pressure) is adjusted to a second pressure lower than the first pressure. Then, the boat 3 is rotated at a predetermined rotating speed by the rotation mechanism 14. In addition, the inside temperature of the process chamber 4 (in-furnace temperature) is increased to a predetermined process temperature.

After that, O₂ gas and H₂ gas are supplied into the process chamber 4 by the oxygen supply nozzle 7a and the hydrogen supply nozzle 7b, respectively. That is, by opening the on-off valves 91a and 93a, O₂ gas whose flow rate is controlled by the mass flow controller 92a is supplied into the process chamber 4 through the oxygen supply pipe 70a by the oxygen supply nozzle 7a. In addition, by opening the on-off valves 91b and 93b, H₂ gas whose flow rate is controlled by the mass flow controller 92b is supplied into the process chamber 4 through the hydrogen supply pipe 70b by the hydrogen supply nozzle 7b.

At this time, the oxygen supply nozzle 8a and the hydrogen supply nozzle 8b also supply O₂ gas and H₂ gas into the process chamber 4, respectively. That is, by opening the on-off valves 94a and 96a, O₂ gas whose flow rate is controlled by the mass flow controller 95a is supplied into the process chamber 4 through the oxygen supply pipe 80a by the oxygen supply nozzle 8a. In addition, by opening the on-off valves 94b and 96b, H₂ gas whose flow rate is controlled by the mass flow controller 95b is supplied into the process chamber 4 through the hydrogen supply pipe 80b by the hydrogen supply nozzle 8b. The O₂ gas supplied from the oxygen supply nozzle 8a and the H₂ gas supplied from the hydrogen supply nozzle 8b are supplied into the process chamber 4 from a plurality of locations of the region corresponding to the wafer arrangement region.

In this manner, O₂ gas and the H₂ gas are supplied from one end side of the wafer arrangement region inside the process chamber 4 (that is, O₂ gas and H₂ gas are supplied through the buffer chamber 12a), and along with this, O₂ gas and H₂ gas are supplied from the plurality of locations of the region corresponding to the wafer arrangement region inside the process chamber 4. The O₂ gas and the H₂ gas supplied into the process chamber 4 flow down in the inside of the process chamber 4 and are exhausted through the gas exhaust outlet 11 installed at the other end side of the wafer arrangement region.

The O₂ gas supplied through the oxygen supply nozzle 7a, and the H₂ gas supplied through the hydrogen supply nozzle 7b are first mixed with each other and react with each other in the buffer chamber 12a. By this, intermediate products such as H, O, and OH are produced. Then, the mixture of the O₂ gas and the H₂ gas including such intermediate products are supplied into the process chamber 4 through the shower plate 12 in a shower-shaped fashion. As disclosed in the specification of Japanese Patent Application No. 2008-133772, filed by the present applicant, among such intermediate products, a representative intermediate product that directly contributes to formation of oxide films is atomic oxygen O, and other intermediate products such as H and OH do not participate in surface reaction that is related with formation of oxide films. That is, among intermediate products generated by reaction between O₂ gas and H₂ gas, atomic oxygen O functions as a reaction species (oxidation species) so that an oxidation process can be performed on the wafers 6 to form silicon oxide (SiO₂) films as oxide films on the surfaces of the wafers 6.

For this, the inside temperatures of the buffer chamber 12a and the process chamber 4 are set in the range from 500° C. to 700° C. The inside pressure of the buffer chamber 12a is set to a first pressure lower that atmospheric pressure, and the inside pressure of the process chamber 4 is set to a second pressure lower than the first pressure. Then, in the buffer chamber 12a, O₂ gas and H₂ gas react with each other to produce an oxidation species (atomic oxygen O) in a manner such that the concentration of the atomic oxygen O becomes highest at ejection-hole positions where the atomic oxygen is ejected from the buffer chamber 12a into the process chamber 4. That is, so as to make the concentration of atomic oxygen O highest at the ejection-hole positions where the atomic oxygen is ejected from the buffer chamber 12a into the process chamber 4, the inside pressure of the buffer chamber 12a, and stay times of the respective gases are properly set. In addition, the inside pressure of the process chamber 4 is set in a manner such that after O₂ gas and H₂ gas are ejected through the ejection holes of the buffer chamber 12a, the O₂ gas and the H₂ gas do not react with each other and thus an oxidation species (atomic oxygen O) is not produced.

In the above-described structure, if O₂ gas and H₂ gas are supplied only through the oxygen supply nozzle 7a and the hydrogen supply nozzle 7b (that is, only through the main nozzle), for example, a trend (similar to the case of the loading effect) in which the thickness of oxide films is gradually reduced as shown by the solid curve in FIG. 5 can be made. Owing to the trend made as described above, film thickness distribution can be effectively corrected between wafers by supplementarily supplying H₂ gas through the hydrogen supply nozzle 8b.

That is, the concentration of atomic oxygen O can be controlled along the stacked direction of the wafers 6, and correction of thickness distribution of oxide films can be enabled, so that the thickness distribution of oxide films can be kept uniform along the wafer stacked direction. In addition, O₂ gas is supplied through the oxygen supply nozzle 8a to each of the process wafers 6 so as to make uniform the in-surface concentration distribution of atomic oxygen O on each of the process wafers 6. Supply of O₂ gas through the oxygen supply nozzle 8a is optional; however, particularly, it is effective for the case where the thickness distribution of an oxide film in a surface of a wafer has a bowl shape, such as the case where wafers such as patterned wafers that consume a large amount of atomic oxygen O are oxidized or the case where wafers are oxidized at a high pressure of about 100 Pa or higher. In the above-described description, the first pressure means a pressure suitable for decomposition of O₂ and H₂. The inside pressure of the buffer chamber 12a, and stay times of respective gases in the buffer chamber 12a may be adjusted according to the volume of the buffer chamber 12a, the number or size of the ejection holes formed in the shower plate 12, the thickness of the shower plate 12, etc.

Exemplary process conditions of a wafer oxidation process are as follows:

Inside temperature of buffer chamber 12a: 500° C. to 700° C.,

Inside temperature of process chamber 4: 500° C. to 700° C.,

First pressure (inside pressure of buffer chamber 12a): 1,000 Pa to 2,000 Pa,

Second pressure (inside pressure of process chamber 4): 1 Pa to 1,000 Pa,

Oxygen gas supply flow rate supplied through main nozzle: 2,000 sccm to 4,000 sccm,

Hydrogen gas supply flow rate supplied through main nozzle: 200 sccm to 500 sccm,

Oxygen gas supply flow rate supplied through sub-nozzle (total flow rate): 0 to 3,000 sccm, and

Hydrogen gas supply flow rate supplied through sub-nozzle (total flow rate): 1,500 sccm to 2,000 sccm.

While maintaining the respective process conditions at constant values within the respective ranges, the oxidation process is performed on the wafers 6.

When the oxidation process of the wafers 6 is completed, the on-off valves 91a, 91b, 93a, 93b, 94a, 94b, 96a and 96b are closed, and supply of O₂ gas and H₂ gas into the process chamber 4 is stopped. Then, by vacuum-exhausting the inside of the reaction tube 10 or purging the inside of the reaction tube 10 with inert gas, residual gases inside the reaction tube 10 are removed. Subsequently, after the in-furnace pressure is returned to atmospheric pressure and the in-furnace temperature is decreased to a predetermined temperature, the boat 3 holding the processed wafers 6 is unloaded from the inside of the process chamber 4, and the boat 3 is left at a predetermined position until all the processed wafers 6 held in the boat 6 are cooled. If the processed wafers 6 held in the queued boat 3 are cooled to a predetermined temperature, the processed wafers 6 are discharged by the substrate transfer device. In this way, a series of processes for oxidizing the wafers 6 are completed.

Hereinafter, with reference to FIG. 8B and FIG. 11 to FIG. 15, operations of the current embodiment will be described.

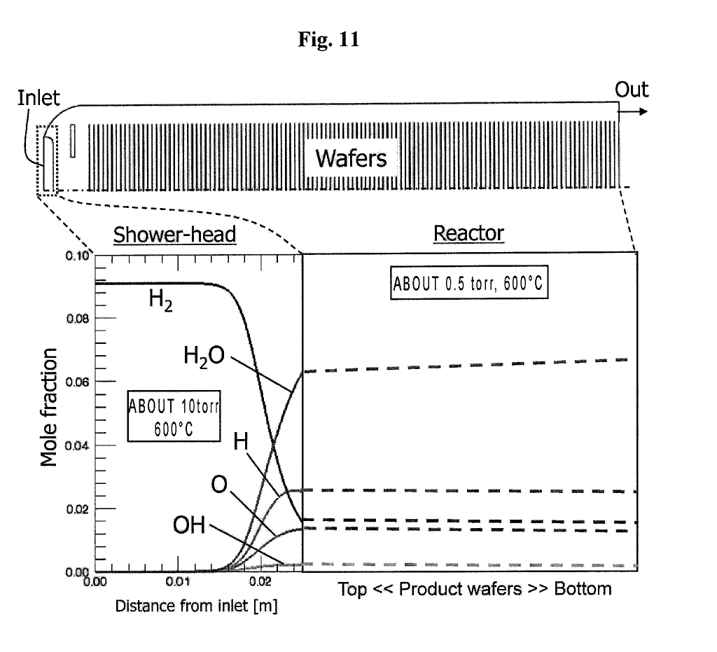

FIG. 11 shows results of CFD analysis performed on the calculation model of FIG. 8B, in the concentration distribution of atomic oxygen O is plotted. FIG. 8B shows a calculation model of a shower head part (corresponding to the buffer chamber 12a of the current embodiment) and a reaction chamber part (corresponding to the process chamber 4 of the current embodiment). The shower head part of FIG. 8B has a cylindrical shape with an inner diameter of φ350 mm and a length of 25 mm. The reaction chamber part of FIG. 8B has the same structure as that of the reaction chamber part of FIG. 8A. In FIG. 11, the horizontal axis denotes the distance from an inlet 9 (equal to stay time), and the vertical axis denotes mole fractions of gas species (H₂, H₂O, H, O, and OH). Since the mole fraction of O₂ is relatively high as compared with the others, the mole fraction of O₂ is not shown. In calculation, gas consumption at wafer surfaces is not considered, and only gas-phase reaction is considered under the assumption that gases are completed mixed with each other.

Although a plurality of gas species are shown in FIG. 11, an explanation will be given mainly on atomic oxygen O because the atomic oxygen O directly contributes to formation of oxide films. Under the follow conditions: the flow rate of O₂ gas is several thousands of sccm, the flow rate of H₂ gas is several hundreds of sccm, the inside temperatures of the shower head part and the reaction chamber part are 600° C., the pressure of the shower head part is about 10 torr (1333 Pa), and the inside pressure of the reaction chamber part is about 0.5 torr (67 Pa), if calculation is executed, as shown in FIG. 11, decomposition reaction becomes active at the distance of about 15 mm from the inlet, and the mole fraction of atomic oxygen O becomes highest at a location close to the outlet of the shower head part (corresponding to the ejection holes of the shower plate 12) that is located at the distance of 25 mm from the inlet. When the atomic oxygen O flows into the reaction chamber part in the state where the concentration of the atomic oxygen O is highest, since gas-phase reaction is slow in the reaction chamber part due to the low inside pressure (about 0.5 torr) of the reaction chamber part, the concentration of the atomic oxygen O is kept almost constant (this is the same to the other gases) as shown by a dashed line in the graph of FIG. 11. Since atomic oxygen O is consumed at the surfaces of wafers when oxide films are actually formed, the concentration of atomic oxygen O is gradually reduced as it goes from the inlet to the outlet. In this case, by supplementarily supplying H₂ gas through the hydrogen supply nozzle 8b, inter-wafer film thickness distribution can be effectively corrected. In addition, by supplementarily supplying O₂ gas through the oxygen supply nozzle 8a, the film thickness distribution in the surface of a wafer can be improved.

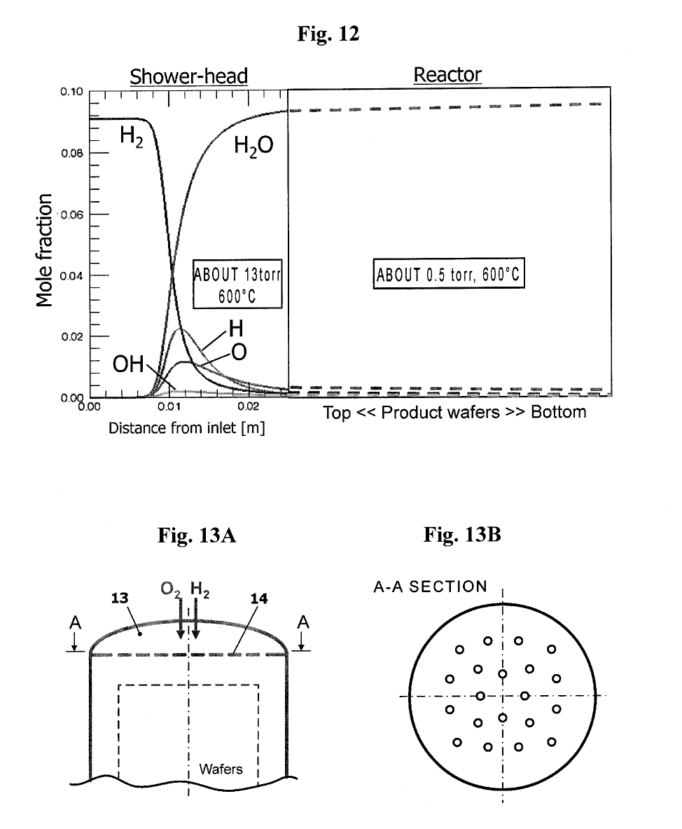

FIG. 12 shows results of CFD analysis performed on the calculation model of FIG. 8B, in which the concentration distribution of atomic oxygen O is plotted when the pressure of the shower head part is increased (to about 13 torr) as compared the pressure of the shower head in FIG. 11. Conditions other than the pressure of the shower head part are the same as the conditions of FIG. 11. Referring to FIG. 12, since the pressure of the shower head part is excessively high, gas-phase reaction excessively proceeds in the shower head part to cause recombination of atomic oxygen O, and thus, the concentration of the atomic oxygen O is low as compared with the case of FIG. 11. If the concentration of the atomic oxygen O is lowered in the shower head part, the concentration of the atomic oxygen O is kept at a low level in the process chamber part. Thus, the growth rate of oxide films is reduced to lower the productivity. From this, it can be understood that controlling of pressure and stay time in the buffer chamber 12a is important.

FIG. 13A is a vertical sectional view showing the buffer chamber 12a, and FIG. 13B is a horizontal sectional view showing the buffer chamber 12a according to the current embodiment. If O₂ gas and H₂ gas are supplied into the buffer chamber 12a as shown in FIG. 13A and FIG. 13B, the inside of the buffer chamber 12a can be kept at a high pressure to facilitate decomposition reaction of the gases and make atomic oxygen O relatively abundant, for example, at a low temperature of 500° C. to 700° C. A proper inside pressure of the buffer chamber 12a, and proper gas stay time inside the buffer chamber 12a may be varied according to the flow rates of O₂ gas and H₂ gas. In the case where at least the flow rate of O₂ gas is several thousands of sccm and the flow rate of H₂ gas is several hundreds of sccm, the inside pressure of the buffer chamber 12a may be set to about 10 torr. The inside pressure of the buffer chamber 12a, and gas stay time in the buffer chamber 12a may be adjusted according to the volume of the buffer chamber 12a, the number or size of the ejection holes of the shower plate 12, the thickness of the shower plate 12, etc.

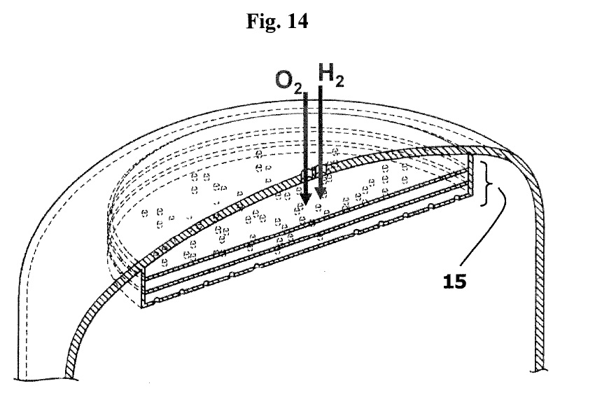

FIG. 14 is a cut-away view illustrating a modification example of the buffer chamber according to an embodiment of the present invention. If decomposition reaction of gases is not sufficiently performed in the buffer chamber 12a shown in FIG. 13, a plurality of shower plates 15 can be used as shown in FIG. 14 so as to increase both the pressure and gas stay time in the buffer chamber 12a. Each of the shower plates 15 may be provided with a plurality of penetration holes arranged in a zigzag fashion. The penetration holes of the shower plates 15 may be not overlapped with each other in vertical directions. In this case, gas passing through the penetration holes of an upper shower plate 15 may not directly pass through the penetration holes of a lower shower plate 15, and thus, pressure and gas stay time can be effectively increased in the buffer chamber 12a.

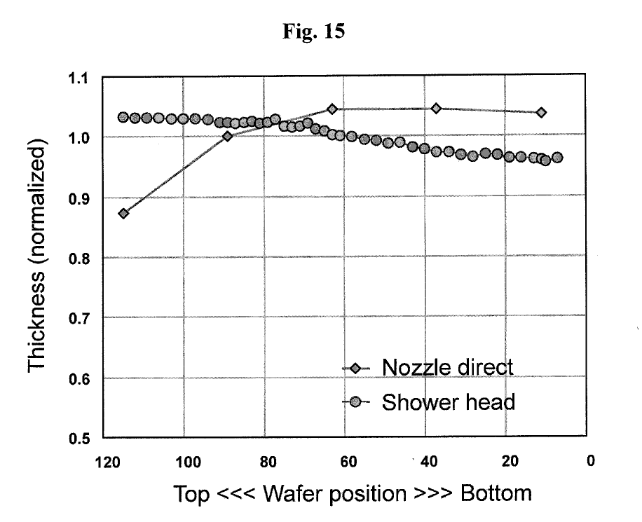

FIG. 15 is a graph showing results of an oxide film forming experiment performed using the heat-treating furnace of the current embodiment, for comparison with results of an oxide film forming experiment performed using a conventional heat-treating furnace. In FIG. 15, the horizontal axis denotes wafer holding position, and the vertical axis denotes film thickness distribution. In the vertical axis of FIG. 15, film thicknesses normalized by the average of all film thicknesses are shown.

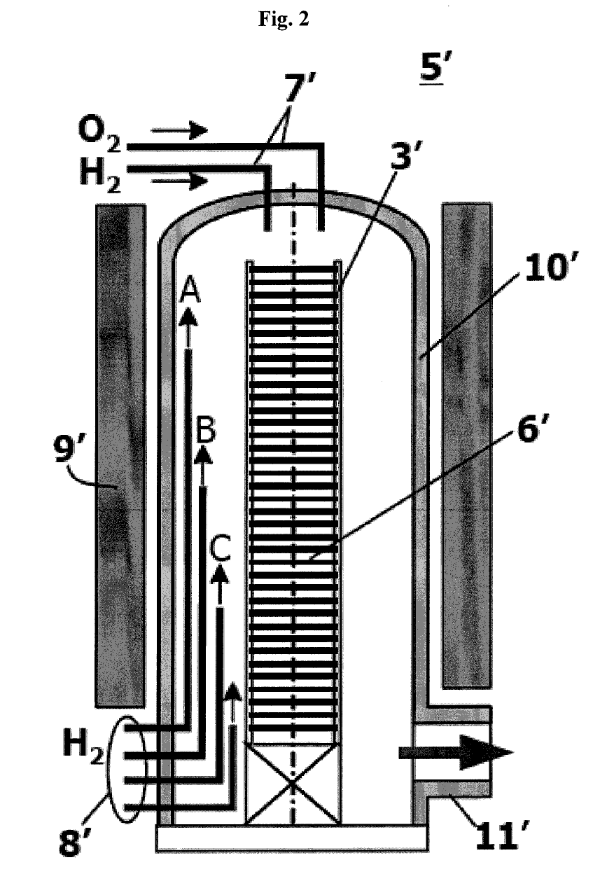

In FIG. 15, a “Nozzle direct” curve indicated by a symbol ⋄ denotes thickness distribution of oxide films formed by the substrate processing apparatus of FIG. 2 or FIG. 3, and a “Shower head” curve indicated by a symbol o denotes thickness distribution of oxide films formed by the substrate processing apparatus of FIG. 7. In both cases of the “Nozzle direct” curve and the “Shower head” curve, oxide films are formed without supplementary supply of H₂ gas or O₂ gas.

In the case of “Nozzle direct” curve (⋄), since decomposition reaction of gases is not sufficient at the top side of the reaction tube 10′ and is slow in the reaction tube 10′, film thickness increases gradually from the top side to the bottom side. In this case, it is difficult to correct the film thickness distribution although hydrogen is supplementarily supplied through the sub-nozzles 8′.

However, in the case of “Shower head” curve (o), since decomposition reaction of hydrogen and oxygen proceeds sufficiently in the buffer chamber 12a, film thickness at the top side can be increased to obtain a trend (similar to the case of a loading effect) in which film thickness decreases gradually as it goes from the top side to the bottom side as shown by experimental results of FIG. 5 indicated by a solid line. Owing to preparation of such a trend, by supplementarily supplying H₂ gas through the hydrogen supply nozzle 8b, the film thickness distribution in the stacked direction of wafers 6 can be effectively corrected. That is, since the concentration of atomic oxygen O can be controlled in the stacked direction of the wafers 6, the film thickness distribution of oxide films can be effectively corrected so as to make uniform the thickness distribution of oxide films in the stacked direction. In addition, by supplementarily supplying O₂ gas through the oxygen supply nozzle 8a, the film thickness distribution in the surface of each wafer 6 can be uniformly improved.

### Another Embodiment of Invention

While embodiments of the present invention have been described in detail, the present invention is not limited thereto, and many different embodiments are possible within the scope and spirit of the present invention.

The present invention may be effective for the case where an oxidation process is performed in a temperature zone, in which oxidation can occur by atomic oxygen O produced by reaction between O₂ gas and H₂ gas at a low pressure, and in which a reverse loading effect can occur. That is, the present invention may be effective for the case where an oxidation process is performed in a temperature zone in which the concentration of atomic oxygen O, which generates by reaction between O₂ gas and H₂ gas supplied into a substrate arrangement region in a direction from one end to the other end of the substrate arrangement region, can be increased as it goes downward. It is found that oxidation reaction occurs at 500° C. or higher when atomic oxygen O generated by reaction between O₂ gas and H₂ gas at a low pressure is used for the oxidation reaction. In addition, it is found that the above-described reverse loading effect, that is, the phenomena in which film thickness increases as it goes from the top side to the bottom side, occurs at 700° C. or lower, particularly, at 600° C. or lower. This corresponds to the calculation results shown in FIG. 10. Therefore, the present invention may be effective for the case where an oxidation process is performed in the temperature range from 500° C. to 700° C., preferably, in the temperature range from 500° C. to 600° C.

As described above, according to the present invention, there are provided a method of manufacturing a semiconductor device at a low temperature of 500° C. to 700° C. while controlling the concentration of atomic oxygen O in a wafer stacked direction and keeping uniform the thickness distribution of oxide films in the wafer stacked direction, and a substrate processing apparatus configured to perform the method.

(Supplementary Note)

The present invention also includes the following preferred embodiments.

According to an embodiment of the present invention, there is provided a method of manufacturing a semiconductor device, the method including: loading a plurality of substrates into a process chamber; oxidizing the substrates by supplying an oxygen-containing gas and a hydrogen-containing gas through a mixing part from an end side of a substrate arrangement region where the substrates are arranged inside the process chamber so that the gases flow toward the other end side of the substrate arrangement region, and supplying a hydrogen-containing gas from a plurality of mid-flow locations corresponding to the substrate arrangement region inside the process chamber; and unloading the plurality of processed substrates from the process chamber, wherein in the oxidizing of the substrates, inside temperatures of the mixing part and the process chamber are set in a range from 500° C. to 700° C., inside pressure of the mixing part is set to a first pressure lower than atmospheric pressure, inside pressure of the process chamber is set to a second pressure lower than the first pressure, and the oxygen-containing gas and the hydrogen-containing gas are allowed to react with each other in the mixing part to produce an oxidation species containing atomic oxygen, so that the oxidation species has a maximum concentration at an ejection hole through which the oxidation species is ejected from the mixing part into the process chamber.

Preferably, in the oxidizing of the substrates, the inside pressure of the mixing part and stay times of the gases in the mixing part may be set such that the oxidation species has a maximum concentration at the ejection hole.

Preferably, in the oxidizing of the substrates, the inside pressure of the process chamber may be set such that after the oxygen-containing gas and the hydrogen-containing gas flow out of the mixing part through the ejection hole, the oxidation species is not produced by reaction between the flowed-out gases.

Preferably, in the oxidizing of the substrates, an oxygen-containing gas may be supplied from a plurality of mid-flow locations corresponding to the substrate arrangement region inside the process chamber.

Preferably, in the oxidizing of the substrates, an oxygen-containing gas may be supplied, from a plurality of mid-flow locations corresponding to the substrate arrangement region inside the process chamber, through as many gas ejection holes as at least the number of the substrates, wherein the gas ejection holes may be in 1:1 correspondence with at least the substrates.

According to another embodiment of the present invention, there is provided a substrate processing apparatus including: a process chamber configured to process a plurality of substrates by oxidation; a holding tool configured to hold the substrates in the process chamber; a mixing part configured to mix an oxygen-containing gas and a hydrogen-containing gas and supply the mixture from an end side of a substrate arrangement region where the substrates are arranged inside the process chamber; a nozzle configured to supply a hydrogen-containing gas from a plurality of mid-flow locations corresponding to the substrate arrangement region inside the process chamber; an exhaust outlet configured to exhaust an inside of the process chamber so that the gases supplied into the process chamber flow toward the other end side of the substrate arrangement region; a temperature control unit configured to set inside temperature of the mixing part and the process chamber in a range from 500° C. to 700° C.; and a pressure control unit configured to set inside pressure of the mixing part to a first pressure lower than atmospheric pressure, and inside pressure of the process chamber to a second pressure lower than the first pressure, wherein the mixing part is configured such that: the oxygen-containing gas and the hydrogen-containing gas are allowed to react with each other in the mixing part to produce an oxidation species containing atomic oxygen, and the oxidation species has a maximum concentration at an ejection hole through which the oxidation species is ejected from the mixing part into the process chamber.

What is claimed is:

1. A method of manufacturing a semiconductor device, the method comprising:
loading a plurality of substrates into a process chamber;
oxidizing the substrates by supplying an oxygen-containing gas and a hydrogen-containing gas through a mixing part from an end side of a substrate arrangement region where the substrates are arranged inside the process chamber so that the gases flow toward the other end side of the substrate arrangement region, and supplying a hydrogen-containing gas from a plurality of mid-flow locations corresponding to the substrate arrangement region inside the process chamber; and
unloading the plurality of processed substrates from the process chamber,
wherein in the oxidizing of the substrates, inside temperatures of the mixing part and the process chamber are set in a range from 500° C. to 700° C., inside pressure of the mixing part is set to a first pressure lower than atmospheric pressure, inside pressure of the process chamber is set to a second pressure lower than the first pressure, and the oxygen-containing gas and the hydrogen-containing gas are allowed to react with each other inside the mixing part to produce an oxidation species containing atomic oxygen, so that the oxidation species has a maximum concentration at an ejection hole through which the oxidation species is ejected from the mixing part into the process chamber.

2. The method of claim 1, wherein in the oxidizing of the substrates, the inside pressure of the mixing part and stay times of the gases in the mixing part are set such that the oxidation species has a maximum concentration at the ejection hole.

3. The method of claim 1, wherein in the oxidizing of the substrates, the inside pressure of the process chamber is set such that after the oxygen-containing gas and the hydrogen-containing gas flow out of the mixing part through the ejection hole, the oxidation species is not produced by reaction between the flowed-out gases.

4. The method of claim 1, wherein in the oxidizing of the substrates, an oxygen-containing gas is supplied from a plurality of mid-flow locations corresponding to the substrate arrangement region inside the process chamber.

5. The method of claim 1, wherein in the oxidizing of the substrates, an oxygen-containing gas is supplied, from a plurality of mid-flow locations corresponding to the substrate arrangement region inside the process chamber, through as many gas ejection holes as at least the number of the substrates, the gas ejection holes being in 1:1 correspondence with at least the substrates.

6. A substrate processing apparatus comprising:
a process chamber configured to process a plurality of substrates by oxidation;
a holding tool configured to hold the substrates in the process chamber;
a mixing part configured to mix an oxygen-containing gas and a hydrogen-containing gas and supply the mixture from an end side of a substrate arrangement region where the substrates are arranged inside the process chamber;
a nozzle configured to supply a hydrogen-containing gas from a plurality of mid-flow locations corresponding to the substrate arrangement region inside the process chamber;
an exhaust outlet configured to exhaust an inside of the process chamber so that the gases supplied into the process chamber flow toward the other end side of the substrate arrangement region;
a temperature control unit configured to set inside temperature of the mixing part and the process chamber in a range from 500° C. to 700° C.; and
a pressure control unit configured to set inside pressure of the mixing part to a first pressure lower than atmospheric pressure, and inside pressure of the process chamber to a second pressure lower than the first pressure,
wherein the mixing part is configured such that:
the oxygen-containing gas and the hydrogen-containing gas are allowed to react with each other in the mixing part to produce an oxidation species containing atomic oxygen, and the oxidation species has a maximum concentration at an ejection hole through which the oxidation species is ejected from the mixing part into the process chamber.

7. The substrate processing apparatus of claim 6, further comprising an additional nozzle configured to supply an oxygen-containing gas from a plurality of mid-flow locations corresponding to the substrate arrangement region inside the process chamber.

8. The substrate processing apparatus of claim 7, where the additional nozzle is configured to supply an oxygen-containing gas through as many gas ejection holes as at least the number of the substrates, the gas ejection holes being in 1:1 correspondence with at least the substrates.
